(19) United States
(12) Patent Application Publication
(10) Pub. No.: US 2026/0182041 A1
(43) Pub. Date: Jun. 25, 2026

(54) DENSELY PACKED BACKSIDE SIGNAL AND POWER TRACKS

(71) Applicant: Intel Corporation, Santa Clara, CA (US)

(72) Inventors: Shaun Mills, Hillsboro, OR (US); Mauro J. Kobrinsky, Portland, OR (US); Joseph D'Silva, Hillsboro, OR (US); Ehren Mannebach, Beaverton, OR (US); Khalil Gabriel El Hajjam, Vancouver, WA (US); Ranjith Kumar, Austin, TX (US); Jonathan Edward Knudsen, Mesa, AZ (US); Naveen Shankarappa Kakarla, Austin, TX (US)

(21) Appl. No.: 18/987,953

(22) Filed: Dec. 19, 2024

(51) Int. Cl. H10D 89/10; H01L 23/528; H10D 30/00; H10D 30/01; H10D 30/47; H10D 30/67; H10D 62/10; H10D 62/13; H10D 84/83

(52) U.S. Cl. CPC H10D 89/10; H10D 30/0191; H10D 30/47; H10D 30/502; H10D 30/6735; H10D 30/6757; H10D 62/118; H10D 62/151; H10D 84/832; H10W 20/427

(57) ABSTRACT

Techniques are provided herein to form semiconductor devices within a standard unit cell having backside metal tracks that include both signaling and power tracks. In an example, each of first and second power tracks are aligned along or otherwise straddle a corresponding one of first and second boundaries of the standard unit cell, with one or more signaling tracks being between the first and second boundaries. Two different semiconductor devices of a given cell may include, for instance, a p-channel device and an n-channel device. Both frontside and backside contacts may be formed to contact either top or bottom surfaces of corresponding source or drain regions included in the unit cell. Backside metal tracks both at the cell boundaries and between the cell boundaries may be formed to electrically couple with the backside contacts of the source or drain regions.

### BACKGROUND

As integrated circuits continue to scale downward in size, a number of challenges arise. For instance, reducing the size of memory and logic cells or otherwise increasing device density is becoming increasingly more difficult. Providing a sufficient number of interconnect lines to each transistor becomes complicated due to space restrictions and parasitic signal effects. Accordingly, there are many non-trivial challenges involved with the fabrication of densely packed semiconductor devices.

### BRIEF DESCRIPTION OF THE DRAWINGS

FIGS. 1A and 1B are cross-sectional views of an example integrated circuit having backside signal and power tracks within a standard unit cell, in accordance with an embodiment of the present disclosure.

FIGS. 2A and 2B are cross-sectional views that illustrate one stage in an example process for forming an integrated circuit having backside signal and power tracks, in accordance with an embodiment of the present disclosure.

FIGS. 3A and 3B are cross-sectional views that illustrate another stage in the example process for forming an integrated circuit having backside signal and power tracks, in accordance with an embodiment of the present disclosure.

FIGS. 4A and 4B are cross-sectional views that illustrate another stage in the example process for forming an integrated circuit having backside signal and power tracks, in accordance with an embodiment of the present disclosure.

FIGS. 5A and 5B are cross-sectional views that illustrate another stage in the example process for forming an integrated circuit having backside signal and power tracks, in accordance with an embodiment of the present disclosure.

FIGS. 6A and 6B are cross-sectional views that illustrate another stage in the example process for forming an integrated circuit having backside signal and power tracks, in accordance with an embodiment of the present disclosure.

FIGS. 7A and 7B are cross-sectional views that illustrate another stage in the example process for forming an integrated circuit having backside signal and power tracks, in accordance with an embodiment of the present disclosure.

FIGS. 8A and 8B are cross-sectional views that illustrate another stage in the example process for forming an integrated circuit having backside signal and power tracks, in accordance with an embodiment of the present disclosure.

FIGS. 9A and 9B are cross-sectional views that illustrate another stage in the example process for forming an integrated circuit having backside signal and power tracks, in accordance with an embodiment of the present disclosure.

FIGS. 10A and 10B are cross-sectional views that illustrate another stage in the example process for forming an integrated circuit having backside signal and power tracks, in accordance with an embodiment of the present disclosure.

FIGS. 11A and 11B are cross-sectional views that illustrate another stage in the example process for forming an integrated circuit having backside signal and power tracks, in accordance with an embodiment of the present disclosure.

FIGS. 12A and 12B are cross-sectional views that illustrate another stage in the example process for forming an integrated circuit having backside signal and power tracks, in accordance with an embodiment of the present disclosure.

FIGS. 13A and 13B are cross-sectional views that illustrate another stage in the example process for forming an integrated circuit having backside signal and power tracks, in accordance with an embodiment of the present disclosure.

FIGS. 14A and 14B are cross-sectional views that illustrate another stage in the example process for forming an integrated circuit having backside signal and power tracks, in accordance with an embodiment of the present disclosure.

FIGS. 15A and 15B are cross-sectional views that illustrate another integrated circuit having backside signal and power tracks and frontside signal tracks, in accordance with an embodiment of the present disclosure.

FIGS. 16A and 16B are cross-sectional views that illustrate another integrated circuit having backside a signal track connected to a bottom surface of a gate structure, in accordance with an embodiment of the present disclosure.

FIG. 17 illustrates a cross-section view of a chip package containing one or more semiconductor dies, in accordance with some embodiments of the present disclosure.

FIG. 18 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices within a standard unit cell having backside metal tracks that include both signaling and power tracks. In some examples, the power tracks may be aligned along the boundaries of the standard unit cell with one or more signaling tracks between the power tracks. The techniques can be used in any number of transistor technologies, such as planar, tri-gate (e.g., finFET devices), gate-all-around (GAA) (e.g., nanoribbon), or forksheet transistor configurations. In one example, two different semiconductor devices of a given memory or logic cell such as a synchronous random-access memory (SRAM) cell, or a complementary metal oxide semiconductor (CMOS) cell, include a p-channel device and an n-channel device. The n-channel device and the p-channel device may be, for example, GAA transistors each having any number of nanoribbons extending in the same direction, wherein the n-channel device is located adjacent to the p-channel device. A first source or drain region may be formed at the ends of the nanoribbons of the n-channel device while a second source or drain region may be formed at the ends of the nanoribbons of the p-channel device, such that the first and second source or drain regions are also adjacent to one another. Both frontside and backside contacts may be formed to contact either top or bottom surfaces of the corresponding source or drain regions. Backside metal tracks may be formed to electrically couple with the backside contacts of the source or drain regions. According to some embodiments, the backside metal tracks include tracks aligned at the boundaries of the standard unit cell and one or more tracks between those tracks aligned at the boundaries of the standard unit cell. In some embodiments, a pitch between adjacent backside metal tracks is less than 125 nm or between 75 nm and 125 nm. Numerous variations and embodiments will be apparent in light of this disclosure.

### General Overview

As previously noted above, there remain a number of non-trivial challenges with respect to designing semiconductor devices. For example, providing signal and power connections to all transistor elements within the footprint of a standard unit cell is challenging. The boundaries of a standard unit cell define, for instance, the layout for a single combinatorial field-effect-transistor (CFET) architecture (e.g., one n-channel transistor and one p-channel transistor). In some examples, the CFET architecture in the standard unit cell provides an inverter circuit. The standard unit cell may then be repeated across a larger layout of the integrated circuit. Topside and backside interconnect tracks (e.g., frontside and backside M0 tracks) may be used to provide signal and power to the various transistor elements in a given standard unit cell. Backside interconnect tracks have been used to carry power rail voltage to various transistor elements (e.g., to the source or drain regions). Such backside interconnect tracks do not leave room for any other backside interconnect tracks that could be used for other purposes (e.g., carrying logic or clock signals).

In accordance with an embodiment of the present disclosure, techniques are provided herein to form backside tracks across a CFET standard unit cell that include one or more backside tracks arranged between backside tracks that are aligned at the boundaries of the standard unit cell. In some examples, the backside tracks at the boundaries of the standard unit cell carry rail voltage (e.g., VDD or VSS) while the one or more backside tracks between those carry low-voltage signals (e.g., logic and/or control signals). In some examples, the more densely packed backside tracks may have a pitch of less than 125 nm or between about 75 nm and about 125 nm. Backside vias and/or contacts may be used to form conductive pathways between source or drain regions of the transistors in the standard unit cell and the backside tracks. In some embodiments, a backside via and/or contact may be formed between a gate structure over one or both of the transistors in the standard unit cell and one of the backside tracks. The presence of additional backside tracks within a given standard unit cell can reduce the number of frontside tracks within the standard unit cell, thus reducing the patterning complexity of the frontside tracks and reducing parasitic signal effects. The techniques can be applied to any number of channel configurations, such as planar transistors, finFETs, GAA transistors, and forksheet transistors. Furthermore, the use of backside signal tracks can be used in several different circuit applications, such as in power gating circuits (power conservation circuitry). In some such cases, for instance, the backside signaling tracks can be used to carry clock, logic, and/or control signals to disable portions of circuitry not currently needed, so as to provide power savings, or to carry signals that require a low resistance signal line (e.g., the backside signaling tracks can be made as thick as necessary for the given application while frontside signaling tracks have more limitations on how thick they can be).

According to an embodiment, an integrated circuit includes: a first semiconductor device having a first semiconductor region extending from a first source or drain region in a first direction, a second semiconductor device having a second semiconductor region extending from a second source or drain region in the first direction with the second source or drain region being adjacent to the first source or drain region along a second direction, a first backside contact on a bottom surface of the first source or drain region, a second backside contact on a bottom surface of the second source or drain region, a first backside metal line conductively coupled to the first backside contact, and a second backside metal line conductively coupled to the second backside contact. A pitch along the second direction between the first backside metal line and the second backside metal line is, for example, less than 125 nm.

According to another embodiment, an integrated circuit includes a standard unit cell having a first semiconductor device and a second semiconductor device. The standard unit cell includes a layout that is repeated across at least a portion of the integrated circuit. The first semiconductor device includes: a first semiconductor region extending from a first source or drain region in a first direction, and a first portion of a gate structure extending over the first semiconductor region in a second direction substantially orthogonal to the first direction. The second semiconductor device includes: a second semiconductor region extending from a second source or drain region in the first direction, and a second portion of the gate structure extending over the second semiconductor region in the second direction. The integrated circuit also includes a first backside metal line centrally aligned along a first boundary of the standard unit cell (or otherwise straddles the first boundary such that the boundary passes through the first backside metal line), and a second backside metal line adjacent to the first backside metal line and arranged such that an entire width of the second backside metal line is between the first boundary of the standard unit cell and a second boundary of the standard unit cell. The second boundary is parallel to the first boundary.

According to another embodiment, an electronic device includes a chip package having one or more dies. At least one of the one or more dies includes: a first semiconductor region extending from a first source or drain region in a first direction, a second semiconductor region extending from a second source or drain region in the first direction with the second source or drain region being adjacent to the first source or drain region along a second direction, a gate structure extending along the second direction over both the first semiconductor region and the second semiconductor region, a first backside contact on a bottom surface of the first source or drain region, a second backside contact on a bottom surface of the second source or drain region, a first backside metal line conductively coupled to the first backside contact, and a second backside metal line conductively coupled to the second backside contact. A pitch along the second direction between the first backside metal line and the second backside metal line is, for example, less than 125 nm.

The techniques are suited for use with gate-all-around transistors such as nanowire and nanoribbon transistors, but may also be applicable in some instances to finFET devices or forksheet transistors. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate electrode can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate a particular arrangement of backside tracks where a pitch between adjacent backside tracks is less than 125 nm, or a first backside track straddling a boundary of a given cell and a second backside track completely between boundaries of that cell.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” and the like, may be used herein for ease of description to describe one element or feature's relationship to another element(s) or feature (s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

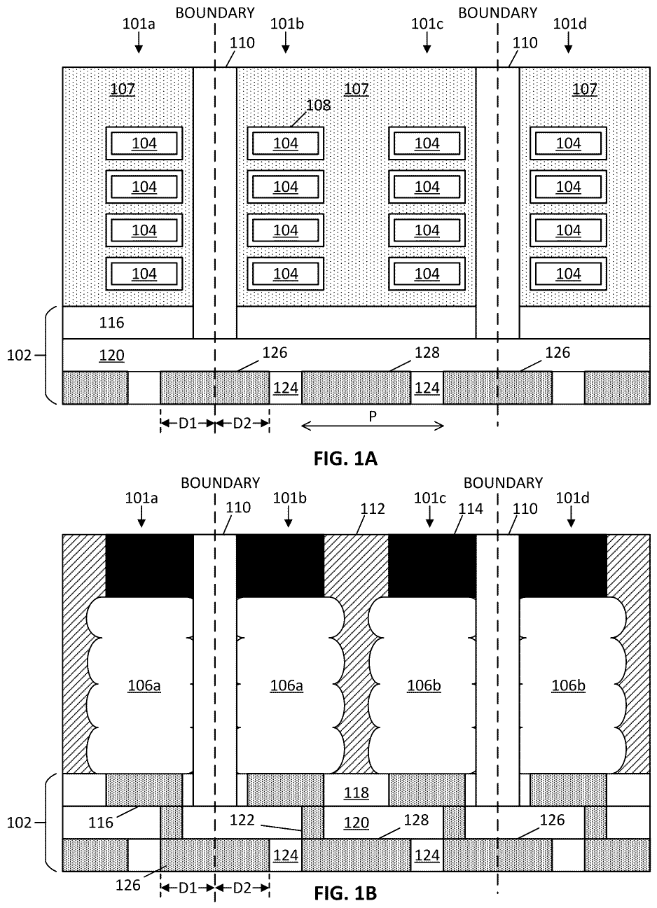

FIGS. 1A and 1B illustrate cross-section views taken across the gate trench (FIG. 1A) and adjacent source/drain trench (FIG. 1B) of a plurality of semiconductor devices 101a-101d, according to some embodiments. Each of semiconductor devices 101a-101d may be non-planar metal oxide semiconductor (MOS) transistors, such as tri-gate or gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions).

As can be seen, semiconductor devices 101a-101d are formed over a base dielectric structure 102. Any number of semiconductor devices can be formed on or over base dielectric structure 102, but four are used here as an example. According to some embodiments, base dielectric structure 102 represents any number of dielectric layers on the backside of the semiconductor devices that may be formed following the removal of a substate from the backside of the structure. In some cases, base dielectric structure 102 is a single layer of dielectric material. In other example cases, base dielectric structure 102 includes two or more distinct depositions of dielectric material, wherein each deposition may be the same dielectric material or different dielectric materials. In some such cases, a seam may be visible between the same (or different) dielectric materials that are deposited at different times. The substate can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. As noted above, the substrate may be removed from the backside and replaced with one or more backside interconnect layers to provide backside power and signal routing.

Each semiconductor device includes one or more nanoribbons 104 extending between epitaxial source or drain regions 106a/106b in a first direction (in/out of page). A gate structure that includes a gate electrode 107 and a gate dielectric 108 extends over the one or more nanoribbons 104 in a second direction (left to right on the page, orthogonal to the first direction) to form the transistor gate. It should be noted that the one or more nanoribbons 104 of each device may also be fins in trigate transistor designs.

The semiconductor material used in each of the semiconductor devices may be formed from the semiconductor substrate (which may be subsequently removed as discussed in more detail herein). As noted above, the one or more semiconductor regions of the devices may include fins that can be, for example, native to the substrate (formed from the substrate itself), such as silicon fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons (such as the illustrated nanoribbons 104) during a gate forming process where one type of the alternating layers are selectively etched away so as to liberate the other type of alternating layers within the channel region, so that a gate-all-around process can then be carried out. Again, the alternating layers can be blanket deposited and then etched into fins or deposited into fin-shaped trenches.

Source or drain regions 106a/106b may be formed at the ends of the one or more nanoribbons 104 of each device, and thus may be aligned along the second direction from one another within a common source/drain trench, as illustrated in FIG. 1B. Note that FIG. 1B illustrates source or drain regions 106a/106b at first ends of nanoribbons 104 and that similar source or drain regions would be formed at opposite ends of nanoribbons 104 in another source/drain trench on the other side of the gate trench. According to some embodiments, source or drain regions 106a/106b are epitaxial regions that are provided at the ends of the semiconductor regions in an etch-and-replace process. Any semiconductor materials suitable for source or drain regions can be used (e.g., group IV and group III-V semiconductor materials). Source or drain regions 106a/106b may include multiple layers such as liners and capping layers to improve contact resistance. Any number of source or drain configurations and materials can be used.

According to some embodiments, source or drain regions 106a represent n-type source or drain regions, and source or drain regions 106b represent p-type source or drain regions, or vice versa. N-type source or drain regions may be epitaxially grown silicon doped with n-type dopants, such as phosphorous or arsenic. p-type source or drain regions may be epitaxially grown silicon germanium doped with p-type dopants, such as boron. According to some embodiments, adjacent n-channel semiconductor device 101b and p-channel semiconductor device 101c are part of a single standard unit cell having cell boundaries indicated by the dashed lines. As noted above, the standard unit cell may be mirrored or repeated about the cell boundaries any number of times across a die.

As noted above, a gate structure extends in the second direction over the one or more nanoribbons 104 of various devices and includes both gate electrode 107 and gate dielectric 108. Gate electrode 107 may include any sufficiently conductive material such as a metal, metal alloy, or doped polysilicon. In some embodiments, gate electrode 107 includes one or more workfunction metals around the one or more semiconductor regions. In some embodiments, p-channel devices include a workfunction metal having tungsten around its one or more semiconductor regions and n-channel devices include a workfunction metal having titanium around its one or more semiconductor regions. Gate electrode 107 may also include a fill metal or other conductive material (e.g., tungsten, ruthenium, molybdenum, or cobalt) around the workfunction metals to provide the whole gate electrode structure. Gate dielectric 108 represents any number of dielectric layers that exist between the one or more nanoribbons 104 and gate electrode 107.

According to some embodiments, gate structures are separated along the second direction by dielectric walls 110, which act like dielectric barriers (e.g., gate cuts) between the gate structures. Dielectric walls 110 effectively isolate the gate structures from one another to form electrically separate gates for each standard unit cell. In the illustrated example, dielectric walls 110 are formed at the boundaries of the standard unit cell. Dielectric walls 110 may be formed from a sufficiently insulating material, such as a dielectric material. Example materials for dielectric walls 110 include silicon nitride, silicon oxide, or silicon oxynitride. In some embodiments, dielectric walls 110 include a dielectric liner and a dielectric fill on the dielectric liner. The dielectric liner may be a high-k dielectric material, such as silicon nitride while the dielectric fill may be a low-k dielectric material such as silicon dioxide or flowable oxide. According to some embodiments, dielectric walls 110 each has a largest width between about 10 nm and about 20 nm.

According to some embodiments, dielectric walls 110 extend in the first direction (along the length of nanoribbons 104) across the gate trench and further along the source/drain trench to isolate adjacent source or drain regions 106a/106b from each other, as illustrated in FIG. 1B. In some examples, dielectric walls 110 separate source or drain regions of the same dopant type (e.g., between n-type source or drain regions 106a and between p-type source or drain regions 106b). In some examples, dielectric walls 110 separate source or drain regions of the opposite dopant type. As noted above, dielectric walls 110 separate all gate structures from one another along the second direction. In some examples, dielectric walls 110 are present between every adjacent pair of source or drain regions 106a/106b regardless of polarity.

According to some embodiments, a dielectric fill 112 may be present between any of source or drain regions 106a/106b along the source/drain trench. Dielectric fill 112 may also be on at least a portion of top surfaces of source or drain regions 106a/106b. Dielectric fill 112 may be any suitable dielectric material, such as silicon dioxide and may have a top surface that is polished to be substantially coplanar with a top surface of dielectric walls 110.

According to some embodiments, one or more topside contacts 114 are provided to make electrical connection with the underlying source or drain regions 106a/106b. Topside contacts 114 may include any suitable conductive material such as tungsten, ruthenium, molybdenum, or cobalt to name a few examples. In the illustrated example, each source or drain region 106a/106b includes a corresponding topside contact 114. However, in some embodiments, one or more source or drain regions 106a/106b do not include topside contact 114 and may instead have a dielectric material (such as dielectric fill 112) on an entirety of their top surface. Similarly, any number of source or drain regions 106a/106b may include a backside contact 116 to make electrical connection beneath the corresponding source or drain region 106a/106b. Backside contacts 116 may include any suitable conductive material such as tungsten, ruthenium, molybdenum, or cobalt to name a few examples. Any number of source or drain regions may not have a backside contact, and instead there may be a dielectric material present along the entire bottom surface of those source or drain regions.

Backside contacts 116 may extend through a first backside dielectric layer 118. In some embodiments, a second backside dielectric layer 120 is formed below first backside dielectric layer 118, and includes any number of conductive vias 122 that contact corresponding backside contacts 116. Conductive vias 122 may include any of the metals noted above for backside contacts 116. According to some embodiments, a third backside dielectric layer 124 is formed below second backside dielectric layer 120 and includes any number of metal lines 126 and 128. Metal lines 126/128 may include any of the metals noted above for backside contacts 116. Each of first backside dielectric layer 118, second backside dielectric layer 120, and third backside dielectric layer 124 may be part of base dielectric structure 102, and may include any suitable dielectric material, such as silicon dioxide.

According to some embodiments, metal lines 126/128 extend parallel to one another along the first direction (e.g., into and out of the page). Metal lines 126/128 may be used to carry power and signals to various semiconductor elements, such as any of source/drain regions 106a/106b. Metal lines 126 may be aligned with corresponding boundaries of the standard unit cell. For example, metal lines 126 may be centrally aligned with the boundaries of the standard unit cell, such that a substantially equal portion or dimension of a given metal line 126 is on either side of a given cell boundary. For instance, and with further reference to the example of FIGS. 1A-B, the distance (D1) from one of the two opposing edges of the given metal line 126 to the boundary is equal to or otherwise within an acceptable tolerance of the distance (D2) from the other one of the two opposing edges of the given metal line 126 to the boundary. Substantially equal in this context may be, for instance, where each of D1 and D2 is within 5% or less of a given target distance, or where D1 is within 5% of D2, or some other suitable tolerance for a given application. In still other examples, a given metal line 126 may straddle a given cell boundary (the given cell boundary passes through the given metal line 126) in an asymmetric fashion, such that D1 is not substantially equal to D2.

According to some embodiments, one or more additional metal lines 128 are arranged between those metal lines 126 at the boundaries of the standard unit cell. In the illustrated example, one additional metal line 128 is arranged between metal lines 126 at the boundaries of the standard unit cell. According to some embodiments, an entire width (along the second direction) of metal line 128 is arranged between the standard cell boundaries along the second direction. In some examples, metal lines 126 at the boundaries are used to carry rail voltage and metal line 128 is used to carry signals (such as logic or clock signals). A pitch P between adjacent metal lines 126/128 along the second direction may be less than 150 nm, less than 125 nm, or between about 75 nm and about 125 nm. It should be noted that conductive vias 122 are optional and may not be present if there is sufficient spacing between source or drain regions 106a/106b to have metal lines 126/128 directly contacting backside contacts 116.

### Fabrication Methodology

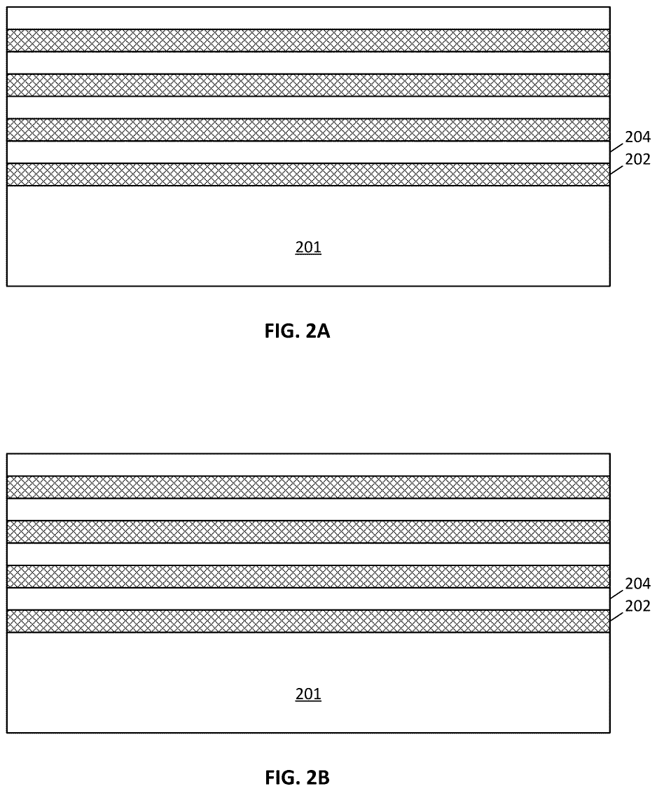

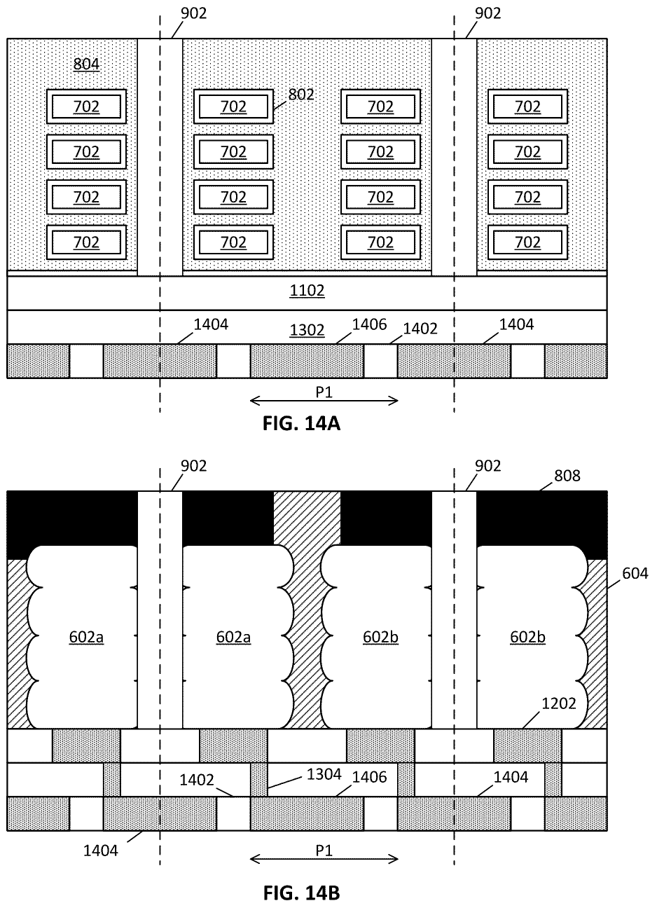

FIGS. 2A-14A and 2B-14B include cross-sectional views that collectively illustrate an example process for forming an integrated circuit that includes densely packed backside signal and power tracks, in accordance with an embodiment of the present disclosure. FIGS. 2A-14A represent cross-sectional views taken across a gate trench of the integrated circuit, while FIGS. 2B-14B represent cross-sectional views taken across the source/drain trench adjacent to the gate trench along the same direction. Each figure shows an example structure that results from the process flow up to that point in time, so the depicted structure evolves as the process flow continues, culminating in the structure shown in FIGS. 14A and 14B, which is similar to the structure shown in FIGS. 1A and 1B, respectively. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated. Figures sharing the same number (e.g., FIGS. 2A and 2B) illustrate different views of the structure at the same point in time during the process flow.

FIGS. 2A and 2B illustrate parallel cross-sectional views taken through a stack of alternating semiconductor layers on a semiconductor substrate 201. FIG. 2A is taken across a portion of the stack that will eventually become a gate trench while FIG. 2B is taken across a portion of the stack that will eventually become a source/drain trench adjacent and parallel to the gate trench. Alternating material layers may be deposited over substrate 201 including sacrificial layers 202 alternating with semiconductor layers 204. The alternating layers are used to form GAA transistor structures. Any number of alternating semiconductor layers 204 and sacrificial layers 202 may be deposited over substrate 201.

Substrate 201 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204.

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Thickness here refers to the vertical direction or up and down the page of FIGS. 2A-B. Each of sacrificial layers 202 and semiconductor layers 204 may be deposited using any known or proprietary material deposition technique, such as chemical vapor deposition (CVD), plasma-enhanced chemical vapor deposition (PECVD), physical vapor deposition (PVD), or atomic layer deposition (ALD).

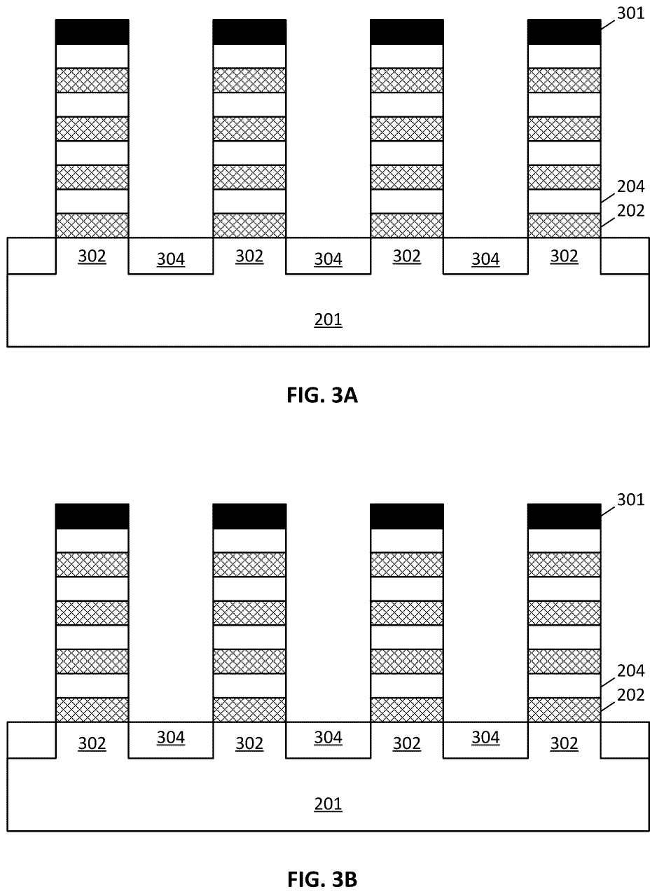

FIGS. 3A and 3B depict the cross-section views of the structure shown in FIGS. 2A and 2B, respectively, following the formation of a cap layer 301 and the subsequent formation of fins beneath cap layer 301, according to an embodiment. Cap layer 301 may be any suitable hard mask material such as a carbon hard mask (CHM) or silicon nitride. Cap layer 301 is patterned into rows to form corresponding rows of fins from the alternating layer stack of sacrificial layers 202 and semiconductor layers 204. The rows of fins extend lengthwise in a first direction (e.g., into and out of the page of each cross-section view).

According to some embodiments, an anisotropic etching process through the layer stack continues into at least a portion of substrate 201, where the unetched portions of substrate 201 beneath the fins form subfin regions 302. The etched portions of substrate 201 may be filled with a dielectric fill 304 that acts as shallow trench isolation (STI) between adjacent fins. Dielectric fill 304 may be any suitable dielectric material such as silicon oxide, and may be recessed to a desired depth as shown (in this example case, down to around the upper surface of subfin regions 302), so as to define the active portion of the fins that will be covered by a gate structure.

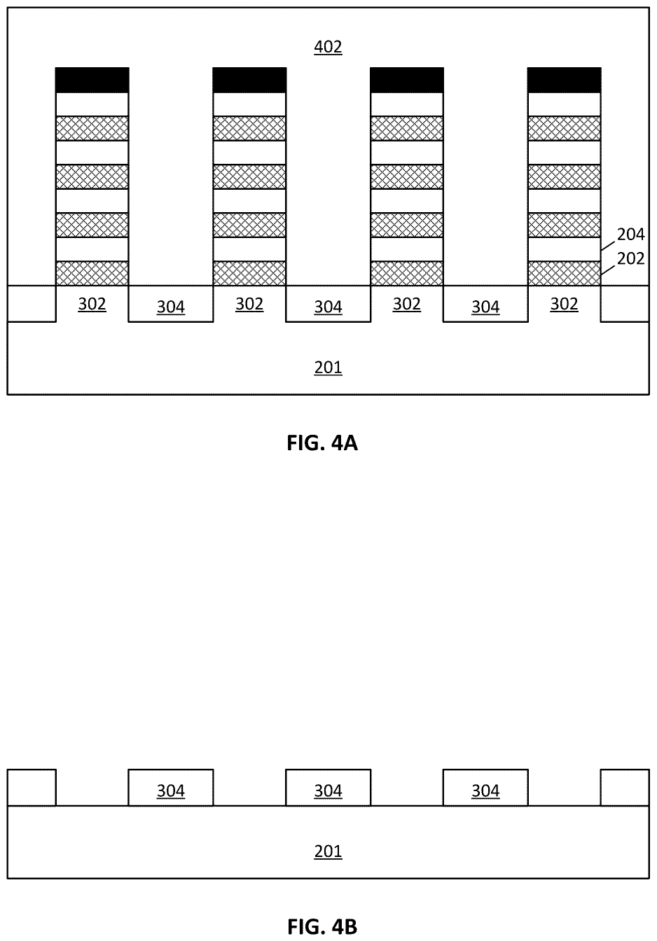

FIGS. 4A and 4B depict the cross-section views of the structure shown in FIGS. 3A and 3B, respectively, following the formation of a sacrificial gate 402 extending across the fins in a second direction different from the first direction, according to some embodiments. Sacrificial gate 402 may extend across the fins in a second direction that is orthogonal to the first direction. According to some embodiments, the sacrificial gate material is formed in parallel strips across the integrated circuit and removed in all areas not protected by a gate masking layer. Sacrificial gate 402 may be any suitable material that can be selectively removed without damaging the semiconductor material of the fins. In some examples, sacrificial gate 402 includes polysilicon.

As seen in the cross-section views, sacrificial gate 402 extends across the fins along the gate trench cross-section of FIG. 4A but is not present along the source/drain trench cross-section of FIG. 4B. Accordingly, sacrificial gate 402 (along with any gate spacers formed on the sidewalls of sacrificial gate 402) protect the underlying portions of the fins while the exposed portions of the fins are etched away as seen in FIG. 4B. According to some embodiments, both semiconductor layers 204 and sacrificial layers 202 are etched at substantially the same rate using an anisotropic reactive ion etching (RIE) process. As observed in FIG. 4B, the RIE process removes both the fins and subfins 302 (or at least portions of subfins 302) above substrate 201. In some embodiments, the RIE process recesses subfin regions 302 beneath at least a top surface of dielectric fill 304. In some embodiments, the RIE process continues to etch deeper beyond subfins 302 and into at least a portion of substrate 201.

According to some embodiments, the exposed portions of sacrificial layers 202 along the edges of the gate spacers may be recessed and the recesses can be filled with internal spacer material. The internal spacer material may be conformally deposited over the exposed ends of the fins and then etched back to fill the recesses with internal spacers while exposing the ends of semiconductor layers 204.

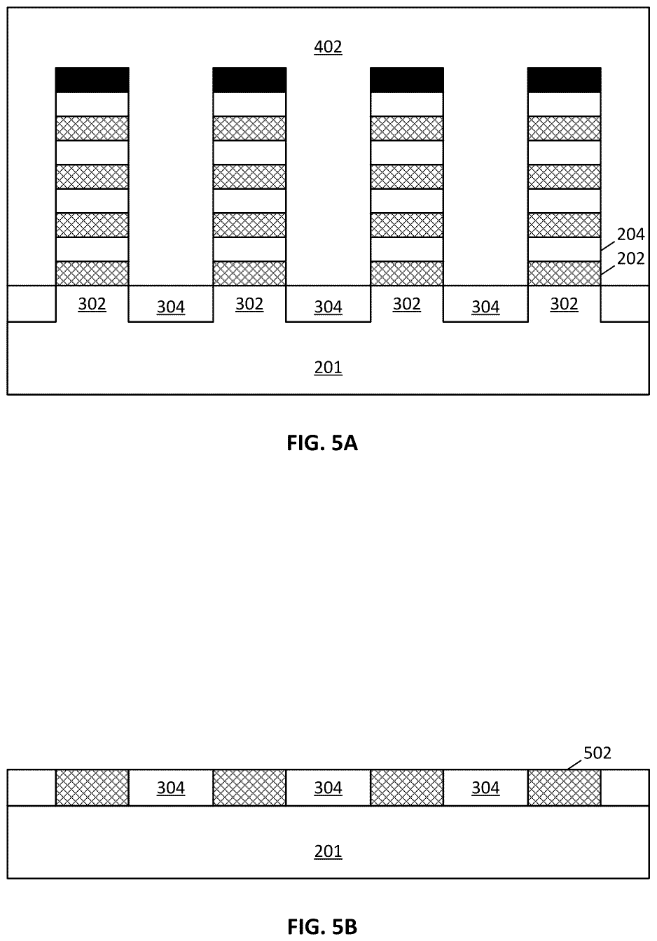

FIGS. 5A and 5B depict the cross-section views of the structure shown in FIGS. 4A and 4B, respectively, following the formation of sacrificial material 502 within the source/drain trench, according to some embodiments. The source/drain trench may be initially filled with sacrificial material 502, according to some embodiments. Sacrificial material 502 may be any suitable material that can be easily removed at a later time without damaging any surrounding structures. In some examples, sacrificial material 502 includes titanium nitride or aluminum oxide. After deposition of sacrificial material 502, it may be recessed to a final thickness such that a top surface of sacrificial material 502 is substantially coplanar (e.g., within 2 nm) of a top surface of dielectric fill 304. In some embodiments, sacrificial material 502 includes a dielectric material having a sufficiently high etch selectivity with the dielectric material of dielectric fill 304. For example, sacrificial material 502 may be silicon nitride while dielectric fill 304 is silicon dioxide.

According to some embodiments, sacrificial material 502 is located in areas where a backside contact to a corresponding source or drain region is desired. It may be preferable to not have a backside contact to one or more source or drain regions. Thus, according to some embodiments, one or more of the plugs of sacrificial material 502 at the bottom of the source/drain trench may be removed and replaced with a dielectric plug, which may be any suitable dielectric material, such as silicon dioxide.

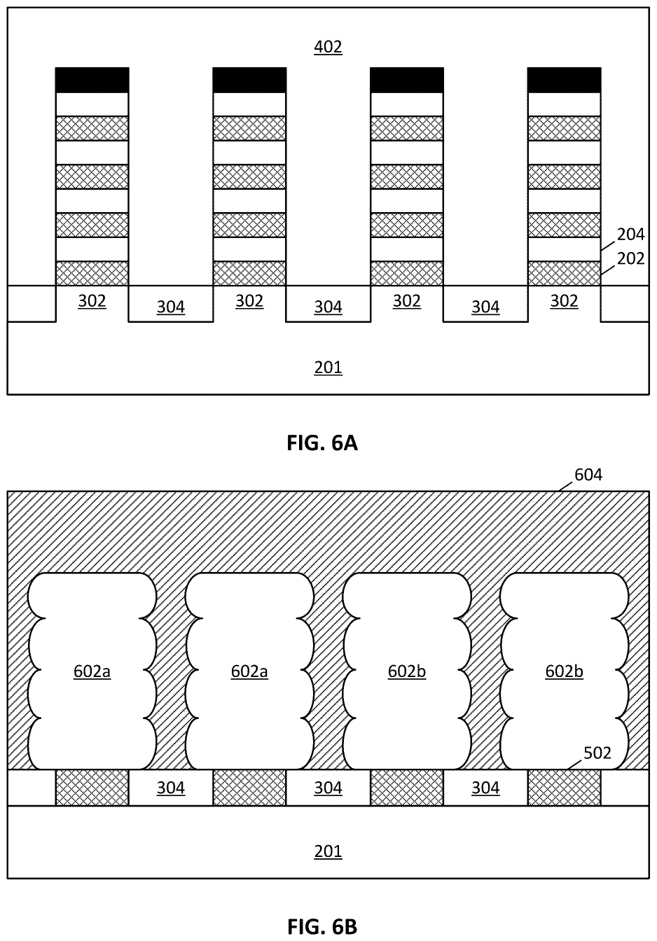

FIGS. 6A and 6B depict the cross-section views of the structure shown in FIGS. 5A and 5B, respectively, following the formation of source or drain regions 602a/602b at the ends of each of the fins (extending into and out of the page in FIG. 6A), according to some embodiments. Source or drain regions 602a/602b may be epitaxially grown from the exposed ends of semiconductor layers 204, such that the material grows together or otherwise merges towards the middle of the source/drain trenches between fins, according to some embodiments. Note that epitaxial growth on one semiconductor layer 204 can fully or partially merge with epitaxial growth on one or more other semiconductor layers 204 in the same vertical stack. The degree of any such merging can vary from one embodiment to the next. In the example of an NMOS device, source or drain regions 602a may be a semiconductor material (e.g., silicon) having a higher dopant concentration of n-type dopants compared to p-type dopants. In the example of a PMOS device, source or drain regions 602b may be a semiconductor material (e.g., silicon germanium) having a higher dopant concentration of p-type dopants compared to n-type dopants. According to some embodiments, the various source or drain regions 602a/602b grown from different semiconductor devices may be aligned along the second direction as shown in FIG. 6B. Source or drain regions 602a/602b may be formed directly on sacrificial material 502. Source or drain regions of one dopant type may all be formed together followed by formation of the source or drain regions of the opposite dopant type.

According to some embodiments, a dielectric fill 604 is provided within the source/drain trench and around source or drain regions 602a/602b. Dielectric fill 604 may extend between adjacent ones of the source or drain regions 602a/602b along the second direction and also may extend up and over each of the source or drain regions 602a/602b, according to some embodiments. Accordingly, each source or drain region 602a/602b may be isolated from any adjacent source or drain regions 602a/602b by dielectric fill 604. Dielectric fill 604 may be any suitable dielectric material, although in some embodiments, dielectric fill 604 includes the same dielectric material as dielectric fill 304. In one example, both dielectric fill 604 and dielectric fill 304 include silicon dioxide. According to some embodiments, a top surface of dielectric fill 604 may be polished using, for example, chemical mechanical polishing (CMP). The top surface of dielectric fill 604 may be polished until it is substantially coplanar with a top surface of sacrificial gate 402.

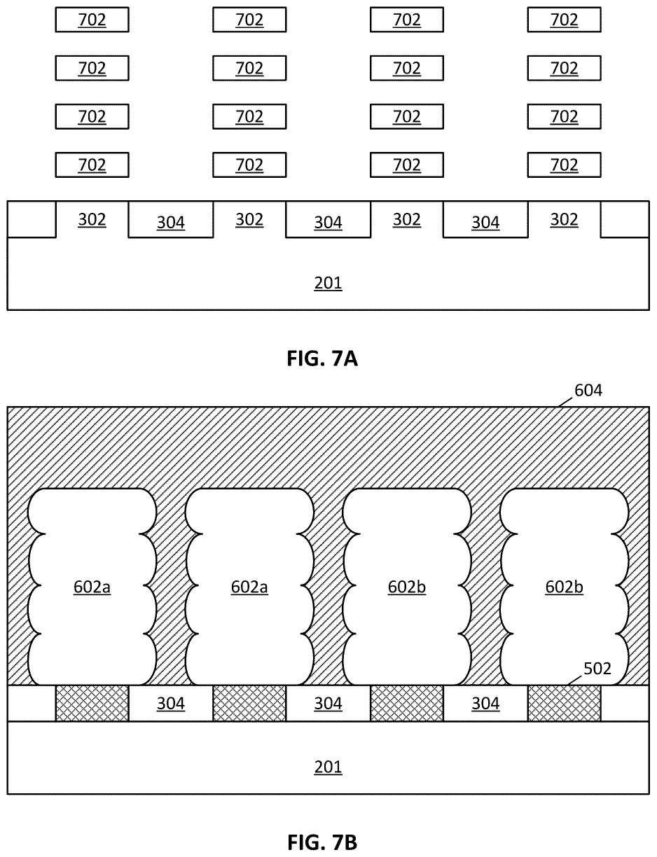

FIGS. 7A and 7B depict the cross-section views of the structure shown in FIGS. 6A and 6B, respectively, following the formation of nanoribbons 702 from semiconductor layers 204, according to some embodiments. Depending on the dimensions of the structures, nanoribbons 702 may also be considered nanowires or nanosheets. Sacrificial gate 402 may be removed using any wet or dry isotropic process thus exposing the alternating layer stack of the fins within the trenches left behind after the removal of sacrificial gate 402. Once sacrificial gate 402 is removed, sacrificial layers 202 may also be removed using a selective isotropic etching process that removes the material of sacrificial layers 202 but does not remove (or removes very little of) semiconductor layers 204 or any other exposed layers (e.g., inner gate spacers). Sacrificial gate 402 and sacrificial layers 202 may be removed together using the same isotropic etching process. At this point, the suspended (sometimes called released) semiconductor layers 204 form nanoribbons 702 that extend in the first direction (into and out of the page) between corresponding source or drain regions 602a/602b and other source or drain regions on the opposite ends of nanoribbons 702.

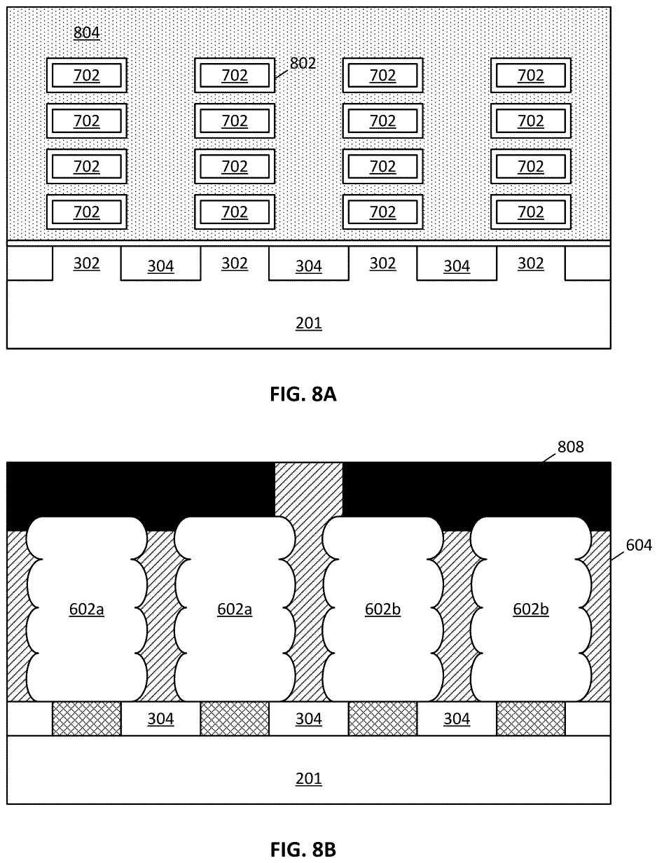

FIGS. 8A and 8B depict the cross-section views of the structure shown in FIGS. 7A and 7B, respectively, following the formation of a gate structure around nanoribbons 702 within the gate trench, according to some embodiments. As noted above, the gate structure includes a gate dielectric 802 and a gate electrode 804. Gate dielectric 802 may be conformally deposited around nanoribbons 702 using any suitable deposition process, such as atomic layer deposition (ALD). Gate dielectric 802 may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 802 is hafnium oxide with a thickness between about 1 nm and about 5 nm. In some embodiments, gate dielectric 802 may include one or more silicates (e.g., titanium silicate, tungsten silicate, niobium silicate, and silicates of other transition metals). Gate dielectric 802 may be a multilayer structure, in some examples. For instance, gate dielectric 802 may include a first layer on nanoribbons 702, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on gate dielectric 802 to improve its quality when a high-k dielectric material is used. In some embodiments, the high-k material can be nitridized to improve its aging resistance. Gate dielectric 802 may form on all exposed surfaces within the gate trench, including on the bottom of the gate trench (e.g., on the top surfaces of subfins 302 and dielectric fill 304).

Gate electrode 804 may be deposited on gate dielectric 802 and can be any standard or proprietary conductive structure. In some embodiments, gate electrode 804 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 804 may include, for instance, one or more workfunction layers, resistance-reducing layers, and/or barrier layers. The workfunction layers can include, for example, p-type workfunction materials (e.g., tungsten) for PMOS gates, or n-type workfunction materials (e.g., titanium aluminum carbide) for NMOS gates.

According to some embodiments, a top portion of gate electrode 804 may be recessed within the gate trench, and the recess is filled with a dielectric material to form a gate cap. The gate cap may be any suitable dielectric material, such as silicon nitride.

According to some embodiments, any number of topside conductive contacts 808 are formed within the source/drain trench and on an upper surface of any number of source or drain regions 602a/602b, according to some embodiments. One or more top portions of dielectric fill 604 may first be recessed until at least a top surface of source or drain regions 602a/602b is exposed. Then, topside conductive contacts 808 may be formed within the recessed cavities above source or drain regions 602a/602b. Topside conductive contacts 808 may include any suitably conductive material such as tungsten, ruthenium, cobalt, titanium, tantalum, molybdenum, or any alloys thereof. A top surface of topside conductive contact 808 may be polished to be substantially coplanar with a top surface of gate electrode 804 (or any gate cap on gate electrode 804). Note that topside conductive contacts 808 may be split into separate contacts over corresponding source or drain regions 602a/602b using dielectric walls as described in the next operation.

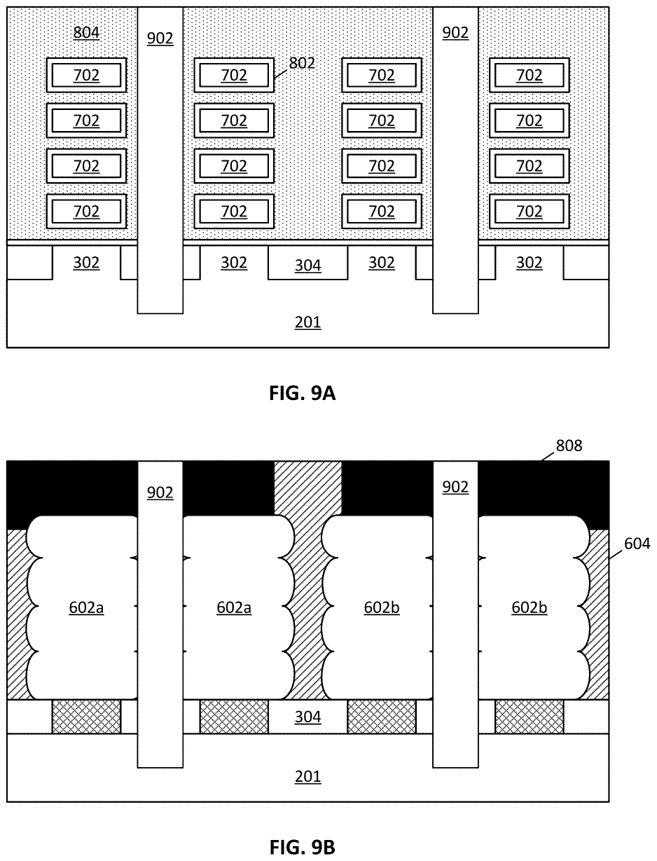

FIGS. 9A and 9B depict the cross-section views of the structure shown in FIGS. 8A and 8B, respectively, following the formation of dielectric walls 902, according to some embodiments. Trench recesses may first be etched through an entire height of the gate structure and through at least a portion of dielectric fill 304. In some examples, the trench recesses are etched through the entire thickness of dielectric fill 304 and into at least a portion of substrate 201. The trench recesses extend along the first direction across any number of gate trenches and source/drain trenches to separate adjacent source or drain regions 602/602b. The trench recesses may be formed at the same time using a reaction ion etching (RIE) process to cut through the various material (while protecting the other regions using a patterned masking layer).

According to some embodiments, the trench recesses are filled with one or more dielectric materials to form dielectric walls 902. According to some embodiments, dielectric walls 902 include a first dielectric layer deposited first and a second dielectric layer or dielectric fill formed on the first dielectric layer. The first dielectric layer may include a high-k dielectric material (e.g., materials with a dielectric constant higher than that of silicon oxide or higher than 3.9, such as silicon nitride) while the second dielectric layer may include a low-k dielectric material (e.g., materials with a dielectric constant equal to or lower than that of silicon oxide, such as porous silicon oxide, or equal to or lower than 3.9). In some embodiments, dielectric walls 902 include only silicon nitride, only silicon oxynitride, or only silicon oxycarbide. Dielectric walls 902 may also be used to separate topside contacts 808 over separate adjacent source or drain regions 602a/602b. In some embodiments, the position of dielectric walls 902 define the boundaries of the standard unit cell that includes at least one n-channel semiconductor device and at least one p-channel semiconductor device. In some embodiments, dielectric walls 902 are present between every adjacent pair of source or drain regions 602a/602b regardless of polarity.

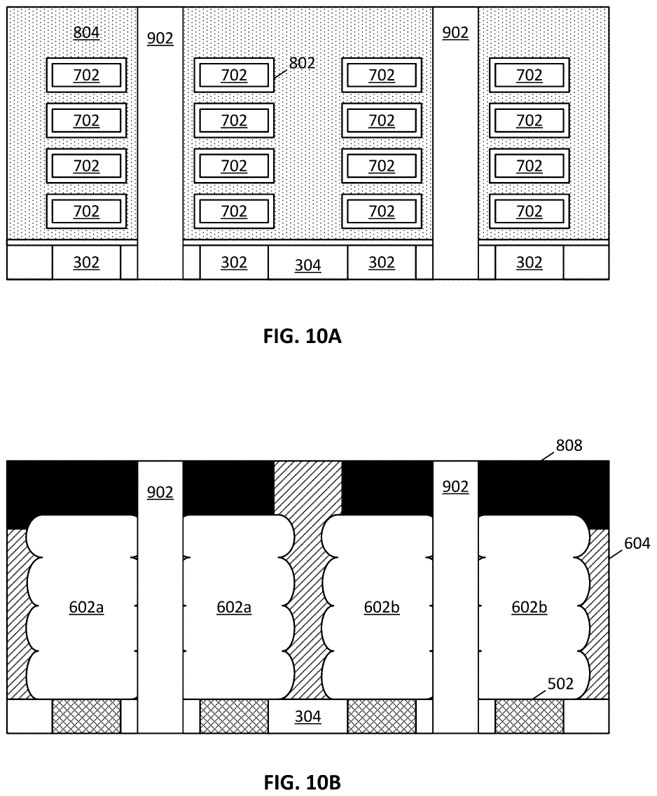

FIGS. 10A and 10B depict the cross-section views of the structure shown in FIGS. 9A and 9B, respectively, following the backside removal of substrate 201, according to some embodiments. Substrate 201 may be polished away via CMP or another grinding process to remove the substrate material. According to some embodiments, substrate 201 continues to be thinned away at least until sacrificial material 502 is exposed from the backside in the source/drain trench. In some examples, portions of subfin regions 302 and/or dielectric fill 304 may also be exposed from the backside in the gate trench. It should be understood that any frontside interconnect structures would be formed prior to the removal of substrate 201.

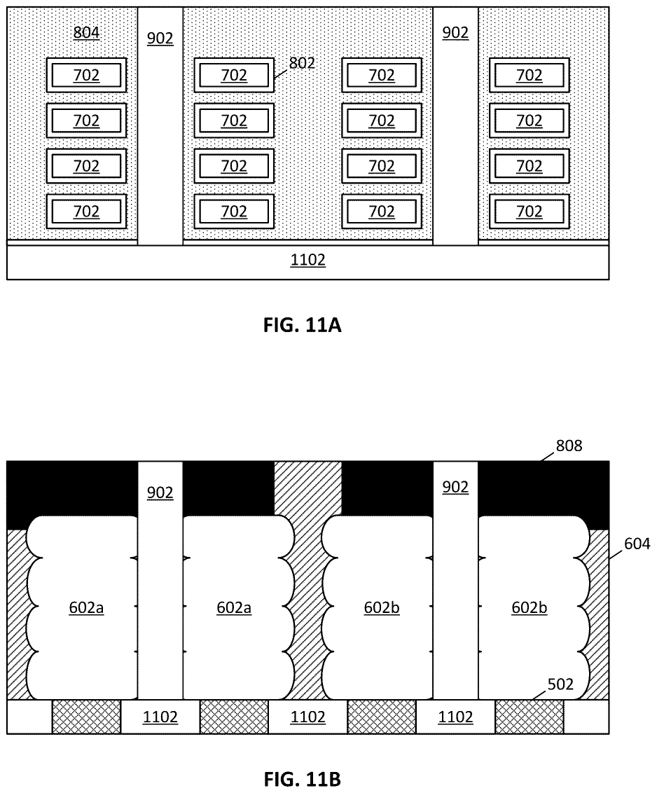

FIGS. 11A and 11B depict the cross-section views of the structure shown in FIGS. 10A and 10B, respectively, following the backside removal of subfin regions 302 and formation of a first backside dielectric layer 1102, according to some embodiments. The exposed subfin regions 302 may be removed using a suitable isotropic semiconductor etching process, or any other suitable semiconductor etching process. The backside cavities left behind from the removal of subfin regions 302 may be filled with another dielectric material, such as the same dielectric material as dielectric fill 304. Accordingly, first backside dielectric layer 1102 may represent the combined dielectric materials of dielectric fill 304 and the dielectric material used to fill the regions previously occupied by subfin regions 302. In some embodiments, dielectric fill 304 is also removed from the backside following a dielectric etching process and a fresh dielectric layer is formed on the backside to form first backside dielectric layer 1102. In any case, the newly deposited dielectric material on the backside of the structure may be polished to expose the bottom surfaces of at least sacrificial material 502.

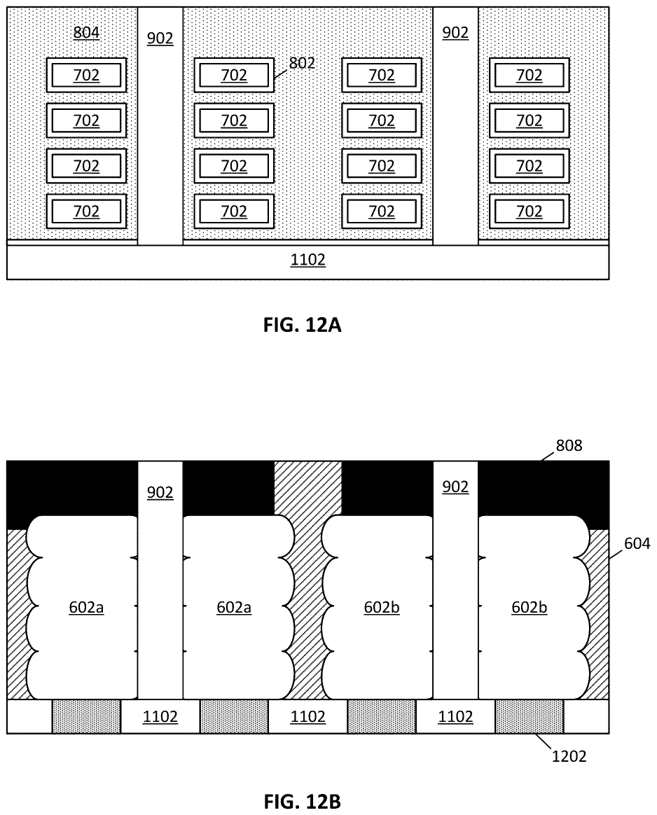

FIGS. 12A and 12B depict the cross-section views of the structure shown in FIGS. 11A and 11B, respectively, following the replacement of sacrificial material 502 with backside contacts 1202, according to some embodiments. Sacrificial material 502 may be selectively removed using any suitable isotropic etching process. Backside contacts 1202 may include any of the same materials discussed above for topside conductive contacts 808 and may be the same conductive material(s) as topside conductive contacts 808. Backside contacts 1202 directly abut a bottom surface of corresponding source or drain regions 602a/602b. The bottom surface of backside contacts 1202 may be polished to be substantially coplanar with the bottom surface of first backside dielectric layer 1102.

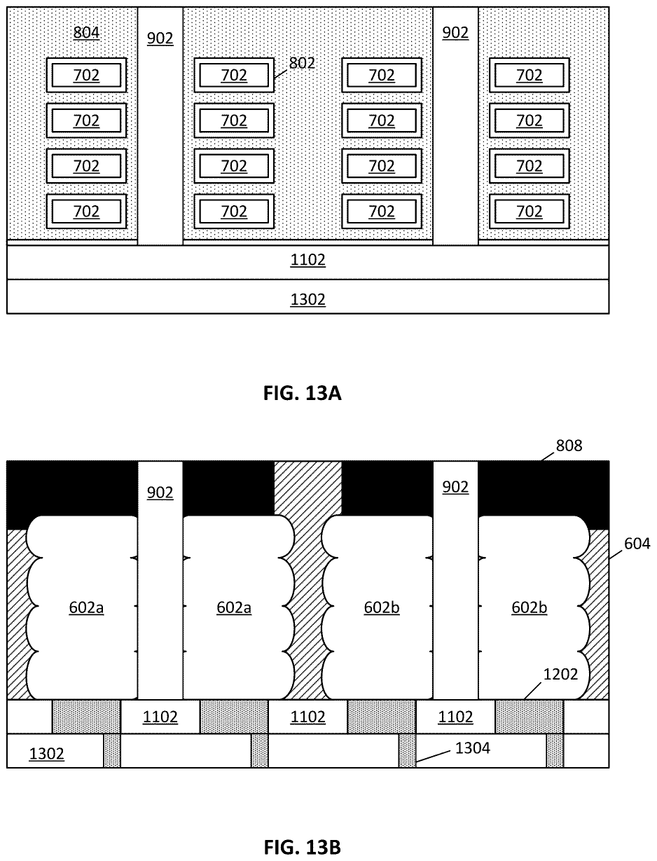

FIGS. 13A and 13B depict the cross-section views of the structure shown in FIGS. 12A and 12B, respectively, following the formation of a second backside dielectric layer 1302 and conductive vias 1304 through second backside dielectric layer 1302, according to some embodiments. Second backside dielectric layer 1302 may be any suitable dielectric material, such as silicon dioxide. According to some embodiments, suitable lithography and etching operations may be performed to form any number of conductive vias 1304 through second backside dielectric layer 1302. Conductive vias 1304 may contact any number of corresponding backside contacts 1202. Conductive vias 1304 may include any of the same materials discussed above for topside conductive contacts 808 and may be the same conductive material(s) as topside conductive contacts 808.

FIGS. 14A and 14B depict the cross-section views of the structure shown in FIGS. 13A and 13B, respectively, following the formation of a third backside dielectric layer 1402 and metal lines 1404/1406 through third backside dielectric layer 1402, according to some embodiments. Third backside dielectric layer 1402 may be any suitable dielectric material, such as silicon dioxide. Suitable lithography and etching operations may be performed to form any number of metal lines 1404/1406 through third backside dielectric layer 1402. According to some embodiments, metal lines 1404 may be aligned at the boundaries of the standard unit cell, while any number of metal lines 1406 are positioned fully within the boundaries of the standard unit cell. As a result, additional backside metal lines are provided for delivering both power and signal to the semiconductor devices. For example, metal line 1404 aligned at the standard unit cell boundary may be a power rail that delivers VDD voltage to source or drain region 602b within the given standard unit cell, while metal line 1406 is a signal line for delivering a clock signal or some other digital signal to source or drain region 602a within the given standard unit cell. A first pitch P1 between adjacent metal lines (e.g., between metal line 1404 at the cell boundary and metal line 1406 within the cell boundary) may be less than 150 nm, less than 125 nm, or between 75 nm and 125 nm. As noted above, some embodiments may not use conductive vias 1304, such that metal lines 1404 are formed directly beneath and contacting corresponding backside contacts 1202. Metal lines 1404 may be include any suitable conductive material, such as tungsten, ruthenium, molybdenum, or cobalt.

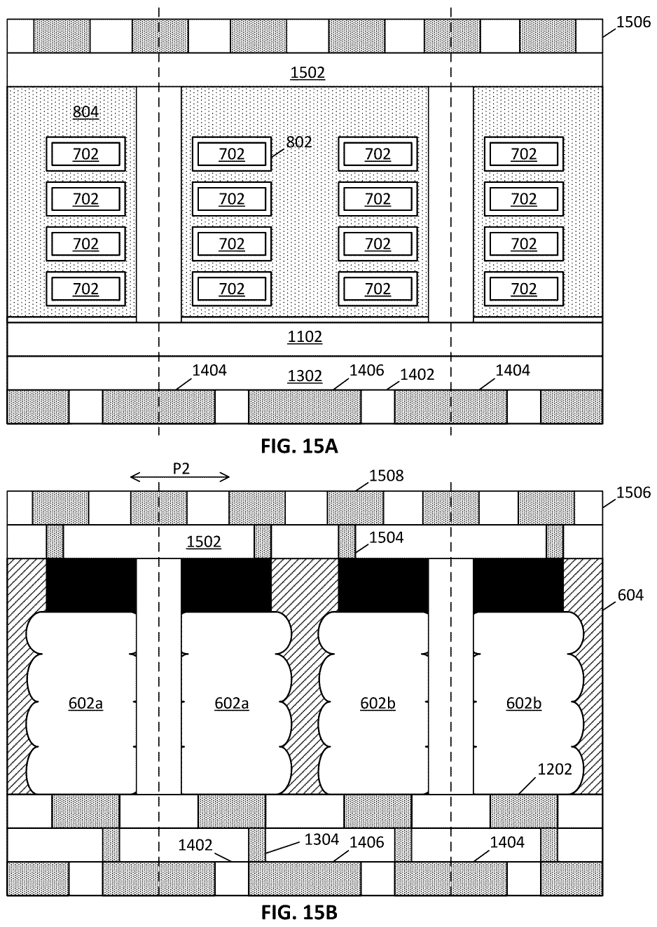

The presence of the additional backside metal lines, such as metal lines 1406, frees up more space for frontside metal lines that carry power or signals to various transistor elements. FIGS. 15A and 15B depict the cross-section views of the structure shown in FIGS. 14A and 14B, respectively, that also includes a frontside interconnect region (formed during back-end-of-the-line processing). The frontside interconnect region includes any number of frontside dielectric layers with metal interconnect structures within the dielectric layers. For example, a first frontside dielectric layer 1502 may include any number of conductive vias 1504 that make electrical connection to underlying source or drain regions 602a/602b or to gate electrode 804. A second frontside dielectric layer 1506 may be formed over first frontside dielectric layer 1502, and may include any number of frontside metal lines 1508. According to some embodiments, frontside metal lines 1508 are arranged to carry various signals between devices and may be identified as signal tracks. A second pitch P2 between adjacent frontside metal lines 1508 may be larger compared to conventional standard cell designs due to the presence of the additional backside metal lines 1406 for carrying signals, thus reducing the total number of frontside metal lines. In some examples, the second pitch P2 is between about 25 nm and about 50 nm. In some examples, fewer frontside metal lines 1508 are required for carrying signals due to the presence of the additional backside metal lines 1406 regardless of any changes in pitch between frontside metal lines 1508.

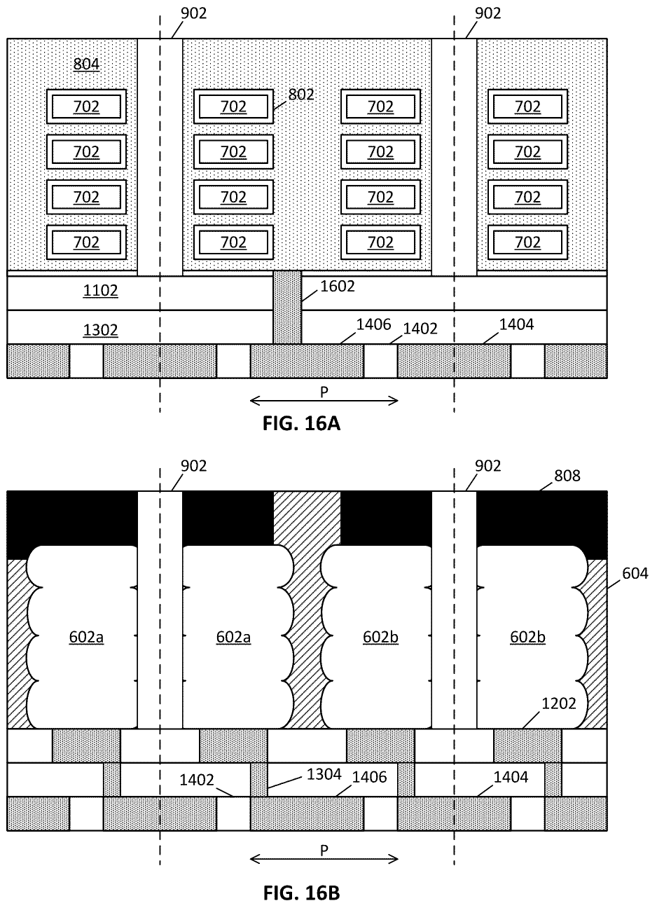

Backside interconnects may be used to connect to other transistor features besides the source or drain regions. FIGS. 16A and 16B illustrate another example integrated circuit structure having a backside gate via 1602 connected between a bottom surface of gate electrode 804 and metal line 1406. Backside gate via 1602 may be formed via an anisotropic etching process using RIE to form a backside cavity through first backside dielectric layer 1102 and second backside dielectric layer 1302, and subsequently filling the backside cavity with any suitable conductive material to form backside gate via 1602. Any number of backside gate vias may be formed in this way. Depending on the application, conductive vias 1304 may or may not be present to couple any of metal lines 1404/1406 to corresponding source or drain regions 602a/602b.

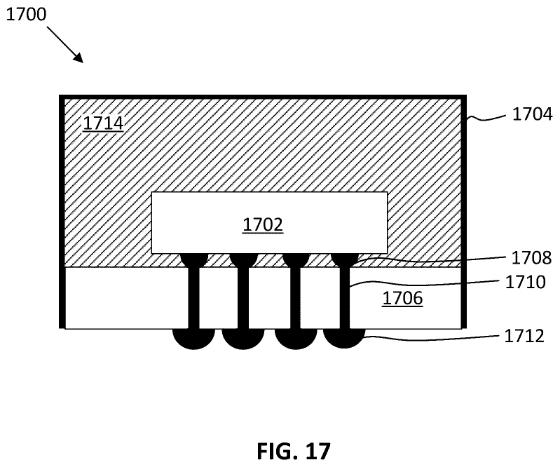

FIG. 17 illustrates an example embodiment of a chip package 1700, in accordance with an embodiment of the present disclosure. As can be seen, chip package 1700 includes one or more dies 1702. One or more dies 1702 may include at least one integrated circuit having semiconductor devices, such as any of the semiconductor devices disclosed herein. One or more dies 1702 may include any other circuitry used to interface with other devices formed on the dies, or other devices connected to chip package 1700, in some example configurations.

As can be further seen, chip package 1700 includes a housing 1704 that is bonded to a package substrate 1706. The housing 1704 may be any standard or proprietary housing, and may provide, for example, electromagnetic shielding and environmental protection for the components of chip package 1700. The one or more dies 1702 may be conductively coupled to a package substrate 1706 using connections 1708, which may be implemented with any number of standard or proprietary connection mechanisms, such as solder bumps, ball grid array (BGA), pins, or wire bonds, to name a few examples. Package substrate 1706 may be any standard or proprietary package substrate, but in some cases includes a dielectric material having conductive pathways (e.g., including conductive vias and lines) extending through the dielectric material between the faces of package substrate 1706, or between different locations on each face. In some embodiments, package substrate 1706 may have a thickness less than 1 millimeter (e.g., between 0.1 millimeters and 0.5 millimeters), although any number of package geometries can be used. Additional conductive contacts 1712 may be disposed at an opposite face of package substrate 1706 for conductively contacting, for instance, a printed circuit board (PCB). One or more vias 1710 extend through a thickness of package substrate 1706 to provide conductive pathways between one or more of connections 1708 to one or more of contacts 1712. Vias 1710 are illustrated as single straight columns through package substrate 1706 for ease of illustration, although other configurations can be used (e.g., damascene, dual damascene, through-silicon via, or an interconnect structure that meanders through the thickness of substrate 1706 to contact one or more intermediate locations therein). In still other embodiments, vias 1710 are fabricated by multiple smaller stacked vias, or are staggered at different locations across package substrate 1706. In the illustrated embodiment, contacts 1712 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1712, to inhibit shorting.

In some embodiments, a mold material 1714 may be disposed around the one or more dies 1702 included within housing 1704 (e.g., between dies 1702 and package substrate 1706 as an underfill material, as well as between dies 1702 and housing 1704 as an overfill material). Although the dimensions and qualities of the mold material 1714 can vary from one embodiment to the next, in some embodiments, a thickness of mold material 1714 is less than 1 millimeter. Example materials that may be used for mold material 1714 include epoxy mold materials, as suitable. In some cases, the mold material 1714 is thermally conductive, in addition to being electrically insulating.

### Example System

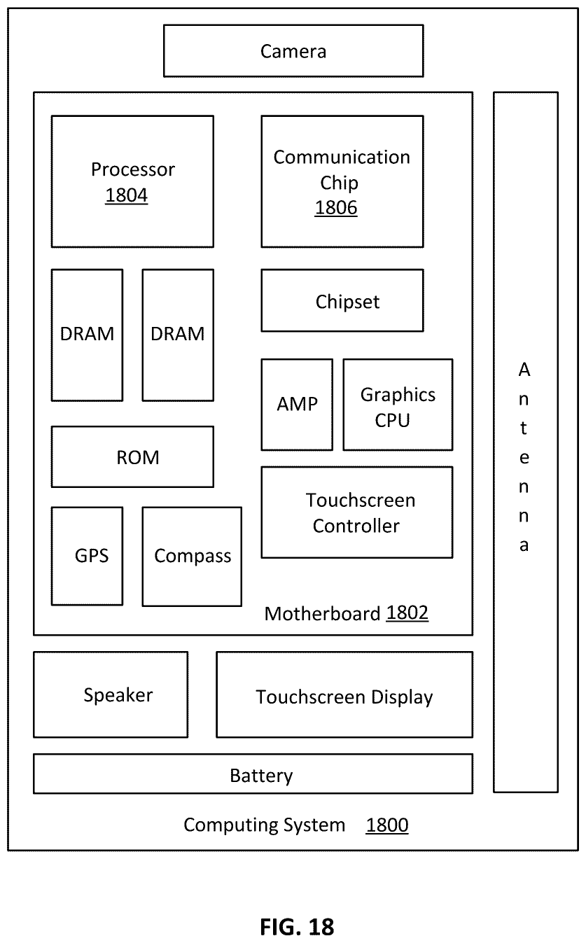

FIG. 18 is an example computing system implemented with one or more of the integrated circuit structures as disclosed herein, in accordance with some embodiments of the present disclosure. As can be seen, the computing system 1800 houses a motherboard 1802. The motherboard 1802 may include a number of components, including, but not limited to, a processor 1804 and at least one communication chip 1806, each of which can be physically and electrically coupled to the motherboard 1802, or otherwise integrated therein. As will be appreciated, the motherboard 1802 may be, for example, any printed circuit board (PCB), whether a main board, a daughterboard mounted on a main board, or the only board of system 1800, etc.

Depending on its applications, computing system 1800 may include one or more other components that may or may not be physically and electrically coupled to the motherboard 1802. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1800 may include one or more integrated circuit structures or devices configured in accordance with an example embodiment (e.g., a module including an integrated circuit having densely packed backside power and signal tracks, as variously provided herein). In some embodiments, multiple functions can be integrated into one or more chips (e.g., for instance, note that the communication chip 1806 can be part of or otherwise integrated into the processor 1804).

The communication chip 1806 enables wireless communications for the transfer of data to and from the computing system 1800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1806 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1800 may include a plurality of communication chips 1806. For instance, a first communication chip 1806 may be dedicated to shorter range wireless communications such as Wi-Fi and Bluetooth and a second communication chip 1806 may be dedicated to longer range wireless communications such as GPS, EDGE, GPRS, CDMA, WiMAX, LTE, Ev-DO, and others.

The processor 1804 of the computing system 1800 includes an integrated circuit die packaged within the processor 1804. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1806 also may include an integrated circuit die packaged within the communication chip 1806. In accordance with some such example embodiments, the integrated circuit die of the communication chip includes one or more semiconductor devices as variously described herein. As will be appreciated in light of this disclosure, note that multi-standard wireless capability may be integrated directly into the processor 1804 (e.g., where functionality of any chips 1806 is integrated into processor 1804, rather than having separate communication chips). Further note that processor 1804 may be a chip set having such wireless capability. In short, any number of processor 1804 and/or communication chips 1806 can be used. Likewise, any one chip or chip set can have multiple functions integrated therein.

In various implementations, the computing system 1800 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1800 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.
Example 1 is an integrated circuit that includes a first semiconductor device having a first semiconductor region extending from a first source or drain region in a first direction, a second semiconductor device having a second semiconductor region extending from a second source or drain region in the first direction with the second source or drain region being adjacent to the first source or drain region along a second direction, a first backside contact on a bottom surface of the first source or drain region, a second backside contact on a bottom surface of the second source or drain region, a first backside metal line conductively coupled to the first backside contact, and a second backside metal line conductively coupled to the second backside contact. A pitch along the second direction between the first backside metal line and the second backside metal line is less than 125 nm.
Example 2 includes the integrated circuit of Example 1, wherein the first source or drain region is an n-type source or drain region, and the second source or drain region is a p-type source or drain region.
Example 3 includes the integrated circuit of Example 1 or 2, wherein the first semiconductor region comprises one or more first semiconductor nanoribbons, and the second semiconductor region comprises one or more second semiconductor nanoribbons.
Example 4 includes the integrated circuit of Example 3, wherein each of the one or more first semiconductor nanoribbons and each of the one or more second semiconductor nanoribbons comprises germanium, silicon, or any combination thereof.
Example 5 includes the integrated circuit of any one of Examples 1-4, further comprising a gate structure extending in the second direction over the first semiconductor region and the second semiconductor region.
Example 6 includes the integrated circuit of Example 5, further comprising a third backside contact coupled to a bottom surface of the gate structure, wherein the first backside metal line or the second backside metal line is conductively coupled to the third backside contact.
Example 7 includes the integrated circuit of any one of Examples 1-6, wherein the first backside metal line is centrally aligned along a first boundary of a standard unit cell that includes the first semiconductor device and the second semiconductor device, and an entire width of the second backside metal line is arranged between the first boundary of the standard unit cell and a second boundary of the standard unit cell, the second boundary being parallel to the first boundary.
Example 8 includes the integrated circuit of any one of Examples 1-7, further comprising a first backside via extending between the first backside contact and the first backside metal line, and a second backside via extending between the second backside contact and the second backside metal line.
Example 9 includes the integrated circuit of any one of Examples 1-8, wherein a first portion of the second backside metal line is directly beneath the first source or drain region, and a second portion of the second backside metal line is directly beneath the second source or drain region.
Example 10 includes the integrated circuit of any one of Examples 1-9, wherein a first width of the first backside metal line is substantially the same as a second width of the second backside metal line.
Example 11 includes the integrated circuit of any one of Examples 1-10, wherein the first direction is orthogonal to the second direction.
Example 12 is a die that includes the integrated circuit of any one of Examples 1-11.
Example 13 is an electronic device that includes a chip package having one or more dies. At least one of the one or more dies includes a first semiconductor region extending from a first source or drain region in a first direction, a second semiconductor region extending from a second source or drain region in the first direction with the second source or drain region being adjacent to the first source or drain region along a second direction, a gate structure extending along the second direction over both the first semiconductor region and the second semiconductor region, a first backside contact on a bottom surface of the first source or drain region, a second backside contact on a bottom surface of the second source or drain region, a first backside metal line conductively coupled to the first backside contact, and a second backside metal line conductively coupled to the second backside contact. A pitch along the second direction between the first backside metal line and the second backside metal line is less than 125 nm.
Example 14 includes the electronic device of Example 13, wherein the first source or drain region is an n-type source or drain region, and the second source or drain region is a p-type source or drain region.
Example 15 includes the electronic device of Example 13 or 14, wherein the first semiconductor region comprises one or more first semiconductor nanoribbons, and the second semiconductor region comprises one or more second semiconductor nanoribbons.
Example 16 includes the electronic device of Example 15, wherein each of the one or more first semiconductor nanoribbons and each of the one or more second semiconductor nanoribbons comprises germanium, silicon, or any combination thereof.
Example 17 includes the electronic device of any one of Examples 13-16, wherein the at least one of the one or more dies further comprises a third backside contact coupled to a bottom surface of the gate structure, wherein the first backside metal line or the second backside metal line is conductively coupled to the third backside contact.
Example 18 includes the electronic device of any one of Examples 13-17, wherein the first backside metal line is centrally aligned along a first boundary of a standard unit cell that includes the first semiconductor region and the second semiconductor region, and an entire width of the second backside metal line is arranged between the first boundary of the standard unit cell and a second boundary of the standard unit cell, the second boundary being parallel to the first boundary.
Example 19 includes the electronic device of any one of Examples 13-18, wherein the at least one of the one or more dies further comprises a first backside via extending between the first backside contact and the first backside metal line, and a second backside via extending between the second backside contact and the second backside metal line.
Example 20 includes the electronic device of any one of Examples 13-19, wherein a first portion of the second backside metal line is directly beneath the first source or drain region, and a second portion of the second backside metal line is directly beneath the second source or drain region.
Example 21 includes the electronic device of any one of Examples 13-20, wherein a first width of the first backside metal line is substantially the same as a second width of the second backside metal line.
Example 22 includes the electronic device of any one of Examples 13-21, wherein the first direction is orthogonal to the second direction.
Example 23 includes the electronic device of any one of Examples 13-22, further comprising a printed circuit board, wherein the chip package is attached to the printed circuit board.
Example 24 is an integrated circuit that includes a standard unit cell having a first semiconductor device and a second semiconductor device. The standard unit cell includes a layout that is repeated across at least a portion of the integrated circuit. The first semiconductor device includes: a first semiconductor region extending from a first source or drain region in a first direction, and a first portion of a gate structure extending over the first semiconductor region in a second direction substantially orthogonal to the first direction. The second semiconductor device includes: a second semiconductor region extending from a second source or drain region in the first direction, and a second portion of the gate structure extending over the second semiconductor region in the second direction. The integrated circuit also includes a first backside metal line straddling a first boundary of the standard unit cell such that a first portion of the first backside metal line is to one side of the first boundary, and a second portion of the first backside metal line is to the other side of the first boundary and a second backside metal line adjacent to the first backside metal line and arranged such that an entire width of the second backside metal line is between the first boundary of the standard unit cell and a second boundary of the standard unit cell. The second boundary extends in the first direction parallel to the first boundary.
Example 25 includes the integrated circuit of Example 24, wherein the first source or drain region is an n-type source or drain region, and the second source or drain region is a p-type source or drain region.
Example 26 includes the integrated circuit of Example 24 or 25, wherein the first semiconductor region comprises one or more first semiconductor nanoribbons, and the second semiconductor region comprises one or more second semiconductor nanoribbons.
Example 27 includes the integrated circuit of Example 26, wherein each of the one or more first semiconductor nanoribbons and each of the one or more second semiconductor nanoribbons comprises germanium, silicon, or any combination thereof.
Example 28 includes the integrated circuit of any one of Examples 24-27, further comprising a first backside contact on a bottom surface of the first source or drain region, and a second backside contact on a bottom surface of the second source or drain region. The first backside metal line is conductively coupled to the first backside contact, and the second backside metal line is conductively coupled to the second backside contact.
Example 29 includes the integrated circuit of Example 28, further comprising a first backside via extending between the first backside contact and the first backside metal line, and a second backside via extending between the second backside contact and the second backside metal line.
Example 30 includes the integrated circuit of any one of Examples 24-29, further comprising a backside contact coupled to a bottom surface of the gate structure, wherein the first backside metal line or the second backside metal line is conductively coupled to the backside contact.
Example 31 includes the integrated circuit of Example 30, wherein the backside contact is a first backside contact, and the integrated circuit further comprises a second backside contact on a bottom surface of the first source or drain region, wherein the first backside metal line is conductively coupled to the first backside contact and the second backside metal line is conductively coupled to the second backside contact.
Example 32 includes the integrated circuit of any one of Examples 24-31, wherein a pitch along the second direction between the first backside metal line and the second backside metal line is less than 125 nm.
Example 33 includes the integrated circuit of Example 32, wherein a distance between the first boundary of the standard unit cell and the second boundary of the standard unit cell along the second direction is between about 150 nm and 250 nm.
Example 34 includes the integrated circuit of any one of Examples 24-33, wherein a first portion of the second backside metal line is directly beneath the first source or drain region, and a second portion of the second backside metal line is directly beneath the second source or drain region.
Example 35 includes the integrated circuit of any one of Examples 24-34, wherein a first width of the first backside metal line is substantially the same as a second width of the second backside metal line.
Example 36 includes the integrated circuit of any one of Examples 24-35, wherein the first direction is orthogonal to the second direction.
Example 37 includes the integrated circuit of any one of Examples 24-36, further comprising a third backside metal line straddling the second boundary of the standard unit cell, such that a first portion of the third backside metal line is to one side of the second boundary, and a second portion of the third backside metal line is to the other side of the second boundary.
Example 38 includes the integrated circuit of Example 37, wherein the third backside metal line is centrally aligned along the second boundary of the standard unit cell.
Example 39 includes the integrated circuit of any one of Examples 24-38, wherein the first backside metal line is centrally aligned along the first boundary of the standard unit cell.
Example 40 is a die that includes the integrated circuit of any one of Examples 24-39.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having a first semiconductor region extending from a first source or drain region in a first direction;
a second semiconductor device having a second semiconductor region extending from a second source or drain region in the first direction, the second source or drain region being adjacent to the first source or drain region along a second direction;
a first backside contact on a bottom surface of the first source or drain region;
a second backside contact on a bottom surface of the second source or drain region;
a first backside metal line conductively coupled to the first backside contact; and
a second backside metal line conductively coupled to the second backside contact,
wherein a pitch along the second direction between the first backside metal line and the second backside metal line is less than 125 nm.

2. The integrated circuit of claim 1, wherein the first source or drain region is an n-type source or drain region, and the second source or drain region is a p-type source or drain region.

3. The integrated circuit of claim 1, further comprising a gate structure extending in the second direction over the first semiconductor region and the second semiconductor region.

4. The integrated circuit of claim 3, further comprising a third backside contact coupled to a bottom surface of the gate structure, wherein the first backside metal line or the second backside metal line is conductively coupled to the third backside contact.

5. The integrated circuit of claim 1, wherein the first backside metal line is centrally aligned along a first boundary of a standard unit cell that includes the first semiconductor device and the second semiconductor device, and an entire width of the second backside metal line is arranged between the first boundary of the standard unit cell and a second boundary of the standard unit cell, the second boundary being parallel to the first boundary.

6. The integrated circuit of claim 1, further comprising:
a first backside via extending between the first backside contact and the first backside metal line; and
a second backside via extending between the second backside contact and the second backside metal line.

7. The integrated circuit of claim 1, wherein a first portion of the second backside metal line is directly beneath the first source or drain region, and a second portion of the second backside metal line is directly beneath the second source or drain region.

8. A die comprising the integrated circuit of claim 1.

9. An electronic device, comprising:
a chip package comprising one or more dies, at least one of the one or more dies comprising
a first semiconductor region extending from a first source or drain region in a first direction;
a second semiconductor region extending from a second source or drain region in the first direction, the second source or drain region being adjacent to the first source or drain region along a second direction;
a gate structure extending along the second direction over both the first semiconductor region and the second semiconductor region;
a first backside contact on a bottom surface of the first source or drain region;
a second backside contact on a bottom surface of the second source or drain region;
a first backside metal line conductively coupled to the first backside contact; and
a second backside metal line conductively coupled to the second backside contact,
wherein a pitch along the second direction between the first backside metal line and the second backside metal line is less than 125 nm.

10. The electronic device of claim 9, wherein the at least one of the one or more dies further comprises a third backside contact coupled to a bottom surface of the gate structure, wherein the first backside metal line or the second backside metal line is conductively coupled to the third backside contact.

11. The electronic device of claim 9, wherein the first backside metal line is centrally aligned along a first boundary of a standard unit cell that includes the first semiconductor region and the second semiconductor region, and an entire width of the second backside metal line is arranged between the first boundary of the standard unit cell and a second boundary of the standard unit cell, the second boundary being parallel to the first boundary.

12. The electronic device of claim 9, wherein a first portion of the second backside metal line is directly beneath the first source or drain region, and a second portion of the second backside metal line is directly beneath the second source or drain region.

13. An integrated circuit comprising:
a standard unit cell having a first semiconductor device and a second semiconductor device, the standard unit cell having a layout that is repeated across at least a portion of the integrated circuit, wherein the first semiconductor device comprises a first semiconductor region extending from a first source or drain region in a first direction, and a first portion of a gate structure extending over the first semiconductor region in a second direction substantially orthogonal to the first direction, and wherein the second semiconductor device comprises a second semiconductor region extending from a second source or drain region in the first direction, and a second portion of the gate structure extending over the second semiconductor region in the second direction;
a first backside metal line straddling a first boundary of the standard unit cell, the first boundary extending in the first direction, such that a first portion of the first backside metal line is to one side of the first boundary, and a second portion of the first backside metal line is to the other side of the first boundary; and
a second backside metal line adjacent to the first backside metal line and arranged such that an entire width of the second backside metal line in the second direction is between the first boundary of the standard unit cell and a second boundary of the standard unit cell, the second boundary extending in the first direction.

14. The integrated circuit of claim 13, further comprising:
a first backside contact on a bottom surface of the first source or drain region; and
a second backside contact on a bottom surface of the second source or drain region,
wherein the first backside metal line is conductively coupled to the first backside contact and the second backside metal line is conductively coupled to the second backside contact.

15. The integrated circuit of claim 14, further comprising:
a first backside via extending between the first backside contact and the first backside metal line; and
a second backside via extending between the second backside contact and the second backside metal line.

16. The integrated circuit of claim 13, further comprising a backside contact coupled to a bottom surface of the gate structure, wherein the first backside metal line or the second backside metal line is conductively coupled to the backside contact.

17. The integrated circuit of claim 16, wherein the backside contact is a first backside contact, and the integrated circuit further comprises a second backside contact on a bottom surface of the first source or drain region, wherein the first backside metal line is conductively coupled to the first backside contact and the second backside metal line is conductively coupled to the second backside contact.

18. The integrated circuit of claim 13, wherein a pitch along the second direction between the first backside metal line and the second backside metal line is less than 125 nm.

19. The integrated circuit of claim 13, further comprising a third backside metal line straddling the second boundary of the standard unit cell, such that a first portion of the third backside metal line is to one side of the second boundary, and a second portion of the third backside metal line is to the other side of the second boundary.

20. The integrated circuit of claim 19, wherein the third backside metal line is centrally aligned along the second boundary of the standard unit cell.
